(19) United States
(12) Patent Application Publication
(10) Pub. No.: US 2014/0099794 A1
(43) Pub. Date: Apr. 10, 2014

(54) RADICAL CHEMISTRY MODULATION AND CONTROL USING MULTIPLE FLOW PATHWAYS

(71) Applicant: Applied Materials, Inc., Santa Clara, CA (US)

(72) Inventors: Nitin K. Ingle, San Jose, CA (US); Anchuan Wang, San Jose, CA (US); Xinglong Chen, San Jose, CA (US)

(73) Assignee: Applied Materials, Inc., Santa Clara, CA (US)

(21) Appl. No.: 13/799,490

(22) Filed: Mar. 13, 2013

Related U.S. Application Data
(60) Provisional application No. 61/704,241, filed on Sep. 21, 2012.

(51) Int. Cl. H01L 21/67; H01L 21/3065

(52) U.S. Cl. CPC H01L 21/67069; H01L 21/3065
USPC 438/710; 156/345.35; 156/345.33; 156/345.36

(57) ABSTRACT

Systems and methods are described relating to semiconductor processing chambers. An exemplary chamber may include a first remote plasma system fluidly coupled with a first access of the chamber, and a second remote plasma system fluidly coupled with a second access of the chamber. The system may also include a gas distribution assembly in the chamber that may be configured to deliver both the first and second precursors into a processing region of the chamber, while maintaining the first and second precursors fluidly isolated from one another until they are delivered into the processing region of the chamber.

### CROSS-REFERENCES TO RELATED APPLICATIONS

This application claims the benefit of U.S. Provisional Application No. 61/704,241, filed Sep. 21, 2012, entitled “Radical Chemistry Modulation and Control Using Multiple Flow Pathways.” The entire disclosure of which is incorporated herein by reference for all purposes.

### TECHNICAL FIELD

The present technology relates to semiconductor processes and equipment. More specifically, the present technology relates to processing systems having multiple plasma configurations.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

A wet HF etch preferentially removes silicon oxide over other dielectrics and semiconductor materials. However, wet processes are unable to penetrate some constrained trenches and sometimes deform the remaining material. Dry etches produced in local plasmas formed within the substrate processing region can penetrate more constrained trenches and exhibit less deformation of delicate remaining structures. However, local plasmas can damage the substrate through the production of electric arcs as they discharge.

Thus, there is a need for improved methods and systems for selectively etching materials and structures on semiconductor substrates that allow more control over precursor chemistries and etch parameters. These and other needs are addressed by the present technology.

### SUMMARY

Systems and methods are described relating to semiconductor processing chambers. An exemplary chamber configured to house a semiconductor substrate in a processing region of the chamber may include a first remote plasma system fluidly coupled with a first access of the chamber, and a second remote plasma system fluidly coupled with a second access of the chamber. The system may also include a gas distribution assembly in the chamber that may be configured to deliver both the first and second precursors into a processing region of the chamber, while maintaining the first and second precursors fluidly isolated from one another until they are delivered into the processing region of the chamber. The first access may be located near or at a top portion of the chamber, and the second access may be located near or at a side portion of the chamber.

The gas distribution assembly may include an upper plate and a lower plate, and the upper and lower plates may be coupled with one another to define a volume between the plates. The coupling of the plates may provide first fluid channels through the upper and lower plates, and second fluid channels through the lower plate. The coupling may also provide fluid access from the volume through the lower plate, and the first fluid channels may be isolated from the volume between the plates and the second fluid channels. The volume may be fluidly accessible through a side of the gas distribution assembly fluidly coupled with the second access in the chamber.

The chamber may be configured to provide the first precursor into the processing region of the chamber from the first remote plasma system through the first access in the chamber and through the first fluid channels in the gas distribution assembly. The chamber may also be configured to provide the second precursor into the chamber from the second remote plasma system through the second access in the chamber into the volume defined between the upper and lower plates and into the processing region of the chamber through the second fluid channels in the gas distribution assembly. The gas distribution assembly may be configured to prevent the flow of the second precursor through the upper plate of the gas distribution assembly. The first remote plasma system may include a first material and the second remote plasma system may include a second material. The first material may be selected based on the composition of the first precursor, and the second material may be selected based on the composition of the second precursor. The first and second materials may be different materials in disclosed embodiments. The first and second remote plasma systems may be selected from the group consisting of RF plasma units, capacitively-coupled plasma units, inductively-coupled plasma units, microwave plasma units, and toroidal plasma units. The first and second remote plasma systems may be configured to operate at power levels between about 10 W to above or about 10 kW. The first remote plasma system may be configured to operate at a first power level that is selected based on the composition of the first precursor, and the second remote plasma system may be configured to operate at a second power level that is selected based on the composition of the second precursor. The system may be configured to operate the first and second remote plasma units at power levels different from one another.

The methods of operation for semiconductor processing chambers may include flowing a first precursor through a first remote plasma system into a semiconductor processing chamber. The methods may also include flowing a second precursor through a second remote plasma system into the semiconductor processing chamber. The first and second precursors may be combined in a processing region of the processing chamber, and may be maintained fluidly isolated from one another prior to entering the processing region of the chamber. The first precursor may include a fluorine-containing precursor, and the second precursor may include a hydrogen-containing precursor in disclosed embodiments.

Such technology may provide numerous benefits over conventional techniques. For example, improved plasma profiles can be used for each of the different plasma systems based on the different precursors. Additionally, system degradation may be lower based on having the different plasma systems formed from materials specific to preventing degradation from the particular precursor that is processed in each system. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing tool.

FIG. 2 shows a schematic cross-sectional view of an exemplary processing chamber.

FIGS. 3A-3D show schematic views of exemplary showerhead configurations according to the disclosed technology.

FIG. 4 shows a simplified cross-sectional view of a processing chamber according to the disclosed technology.

FIG. 5 shows a flowchart of a method of operation for a semiconductor processing chamber according to the disclosed technology.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION OF THE INVENTION

The present technology includes systems for semiconductor processing that provide improved fluid delivery mechanisms. Certain dry etching techniques include utilizing remote plasma systems to provide radical fluid species into a processing chamber. Exemplary methods are described in co-assigned patent application Ser. No. 13/439,079 filed on Apr. 4, 2012, which is incorporated herein by reference to the extent not inconsistent with the claimed aspects and description herein. When dry etchant formulas are used that may include several radical species, the radical species produced from different fluids may interact differently with the remote plasma chamber. For example, precursor fluids for etching may include fluorine-containing precursors, and hydrogen-containing precursors. The plasma cavity of the remote plasma system, as well as the distribution components to the processing chamber, may be coated or lined to provide protection from the reactive radicals. For example, an aluminum plasma cavity may be coated with an oxide or nitride that will protect the cavity from fluorine radicals. However, if the precursors also contain hydrogen radicals, the hydrogen species may convert or reduce the aluminum oxide back to aluminum, at which point the fluorine may react directly with the aluminum producing unwanted byproducts such as aluminum fluoride.

Conventional technologies have dealt with these unwanted side effects through regular maintenance and replacement of components, however, the present systems overcome this need by providing radical precursors through separate fluid pathways into the processing chamber. By utilizing two or more remote plasma systems each configured to deliver separate precursor fluids, each system may be separately protected based on the fluid being delivered. The inventors have also surprisingly determined that by providing the precursor species through separate remote plasma systems, the specific dissociation and plasma characteristics of each fluid can be tailored thereby providing improved etching performance. Accordingly, the systems described herein provide improved flexibility in terms of chemistry modulation. These and other benefits will be described in detail below.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as to etching processes alone.

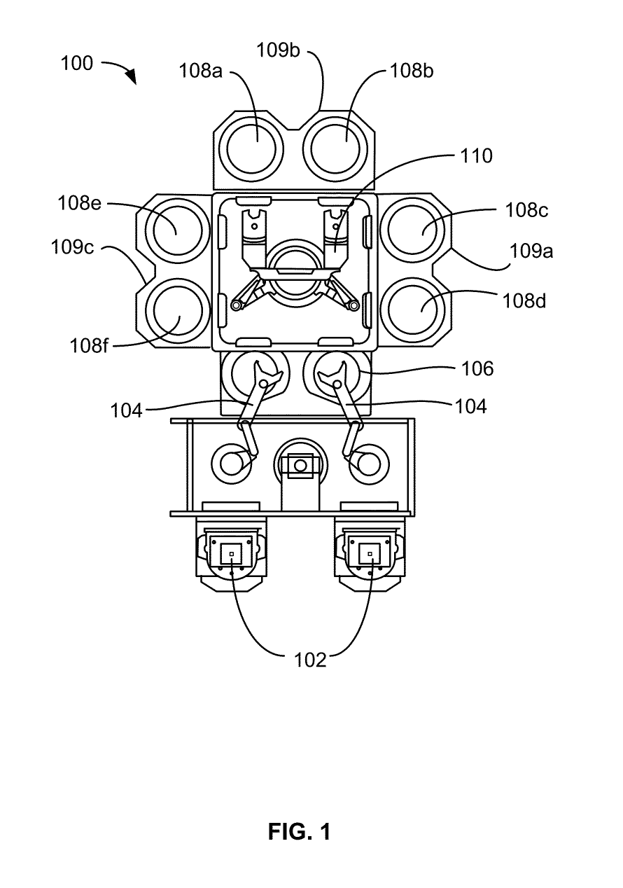

FIG. 1 shows a top plan view of one embodiment of a processing tool 100 of deposition, etching, baking, and/or curing chambers according to disclosed embodiments. In the figure, a pair of FOUPs (front opening unified pods) 102 supply substrates (e.g., specified diameter semiconductor wafers) that may be received by robotic arms 104 and placed into a low-pressure holding area 106 before being placed into one of the substrate processing sections 108a-f of the tandem process chambers 109a-c. A second robotic arm 110 may be used to transport the substrates from the holding area 106 to the processing chambers 108a-f and back.

The substrate processing sections 108a-f of the tandem process chambers 109a-c may include one or more system components for depositing, annealing, curing and/or etching substrates or films thereon. Exemplary films may be flowable dielectrics, but many types of films may be formed or processed with the processing tool. In one configuration, two pairs of the tandem processing sections of the processing chamber (e.g., 108c-d and 108e-f) may be used to deposit the dielectric material on the substrate, and the third pair of tandem processing sections (e.g., 108a-b) may be used to anneal the deposited dielectric. In another configuration, the two pairs of the tandem processing sections of processing chambers (e.g., 108c-d and 108e-f) may be configured to both deposit and anneal a dielectric film on the substrate, while the third pair of tandem processing sections (e.g., 108a-b) may be used for UV or E-beam curing of the deposited film. In still another configuration, all three pairs of tandem processing sections (e.g., 108a-f) may be configured to deposit and cure a dielectric film on the substrate or etch features into a deposited film.

In yet another configuration, two pairs of tandem processing sections (e.g., 108c-d and 108e-f) may be used for both deposition and UV or E-beam curing of the dielectric, while a third pair of tandem processing sections (e.g. 108a-b) may be used for annealing the dielectric film. In addition, one or more of the tandem processing sections 108a-f may be configured as a treatment chamber, and may be a wet or dry treatment chamber. These process chambers may include heating the dielectric film in an atmosphere that includes moisture. Thus, embodiments of system 100 may include wet treatment tandem processing sections 108a-b and anneal tandem processing sections 108c-d to perform both wet and dry anneals on the deposited dielectric film. It will be appreciated that additional configurations of deposition, etching, annealing, and curing chambers for dielectric films are contemplated by system 100.

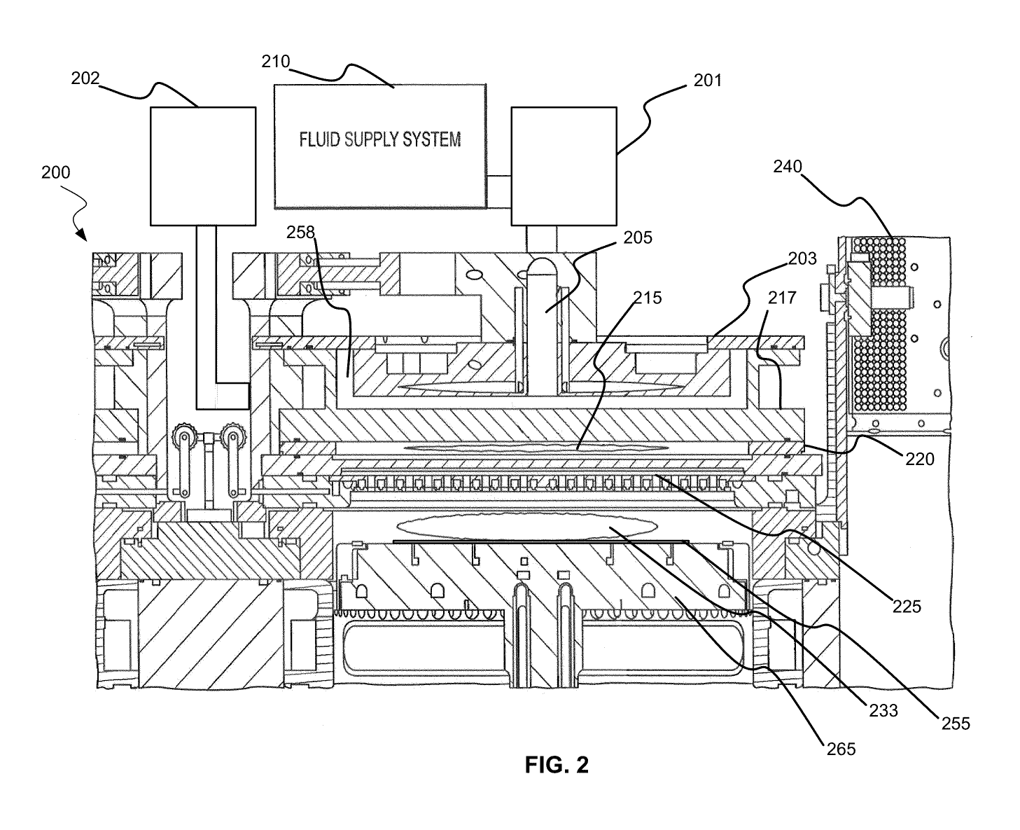

FIG. 2 is a cross-sectional view of an exemplary process chamber section 200 with partitioned plasma generation regions within the processing chambers. During film etching (e.g., silicon, polysilicon, silicon oxide, silicon nitride, silicon oxynitride, silicon oxycarbide), a process gas may be flowed into the first plasma region 215 through a gas inlet assembly 205. A remote plasma system (RPS) 201 may process a first gas which then travels through gas inlet assembly 205, and a second RPS 202 may process a second gas, which then travels through a side inlet in the process chamber 200. The inlet assembly 205 may include two distinct gas supply channels where the second channel (not shown) may bypass the RPS 201. In one example, the first channel provided through the RPS may be used for the process gas and the second channel bypassing the RPS may be used for a treatment gas in disclosed embodiments. The process gas may be excited prior to entering the first plasma region 215 within the RPS 201. A cooling plate 203, faceplate 217, showerhead 225, and a substrate support 265, having a substrate 255 disposed thereon, are shown according to disclosed embodiments. The faceplate 217 may be pyramidal, conical, or of another similar structure with a narrow top portion expanding to a wide bottom portion. The faceplate 217 may additionally be flat as shown and include a plurality of through-channels (not shown) used to distribute process gases. The faceplate (or conductive top portion) 217 and showerhead 225 are shown with an insulating ring 220 in between, which allows an AC potential to be applied to the faceplate 217 relative to showerhead 225. The insulating ring 220 may be positioned between the faceplate 217 and the showerhead 225 enabling a capacitively coupled plasma (CCP) to be formed in the first plasma region. A baffle (not shown) may additionally be located in the first plasma region 215 to affect the flow of fluid into the region through gas inlet assembly 205.

Exemplary configurations include having the gas inlet assembly 205 open into a gas supply region partitioned from the first plasma region 215 by faceplate 217 so that the gases/species flow through the holes in the faceplate 217 into the first plasma region 215. Structural and operational features may be selected to prevent significant backflow of plasma from the first plasma region 215 back into the supply region, gas inlet assembly 205, and fluid supply system 210. The structural features may include the selection of dimensions and cross-sectional geometry of the apertures in faceplate 217 that deactivates back-streaming plasma. The operational features may include maintaining a pressure difference between the gas supply region and first plasma region 215 that maintains a unidirectional flow of plasma through the showerhead 225.

A fluid, such as a precursor, for example a fluorine-containing precursor, may be flowed into the processing region 233 by embodiments of the showerhead described herein. Excited species derived from the process gas in the plasma region 215 may travel through apertures in the showerhead 225 and react with an additional precursor flowing into the processing region 233 from a separate portion of the showerhead. Little or no plasma may be present in the processing region 233. Excited derivatives of the precursors may combine in the region above the substrate and, on occasion, on the substrate to etch structures or remove species on the substrate in disclosed applications.

Exciting the fluids in the first plasma region 215 directly, exciting the fluids in one or both of the RPS units 201, 202, or both, may provide several benefits. The concentration of the excited species derived from the fluids may be increased within the processing region 233 due to the plasma in the first plasma region 215. This increase may result from the location of the plasma in the first plasma region 215. The processing region 233 may be located closer to the first plasma region 215 than the remote plasma system (RPS) 201, leaving less time for the excited species to leave excited states through collisions with other gas molecules, walls of the chamber, and surfaces of the showerhead.

The uniformity of the concentration of the excited species derived from the process gas may also be increased within the processing region 233. This may result from the shape of the first plasma region 215, which may be more similar to the shape of the processing region 233. Excited species created in the RPS 201, 202 may travel greater distances in order to pass through apertures near the edges of the showerhead 225 relative to species that pass through apertures near the center of the showerhead 225. The greater distance may result in a reduced excitation of the excited species and, for example, may result in a slower growth rate near the edge of a substrate. Exciting the fluids in the first plasma region 215 may mitigate this variation for the fluid flowed through RPS 201.

The processing gases may be excited in the RPS 201, 202 and may be passed through the showerhead 225 to the processing region 233 in the excited state. Alternatively, power may be applied to the first processing region to either excite a plasma gas or enhance an already excited process gas from the RPS. While a plasma may be generated in the processing region 233, a plasma may alternatively not be generated in the processing region. In one example, the only excitation of the processing gas or precursors may be from exciting the processing gases in the RPS units 201, 202 to react with one another in the processing region 233.

The processing system may further include a power supply 240 electrically coupled with the processing chamber to provide electric power to the faceplate 217 and/or showerhead 225 to generate a plasma in the first plasma region 215 or processing region 233. The power supply may be configured to deliver an adjustable amount of power to the chamber depending on the process performed.

In addition to the fluid precursors, there may be other gases introduced at varied times for varied purposes, including carrier gases to aid delivery. A treatment gas may be introduced to remove unwanted species from the chamber walls, the substrate, the deposited film and/or the film during deposition. A treatment gas may be excited in a plasma and then used to reduce or remove residual content inside the chamber. In other disclosed embodiments the treatment gas may be used without a plasma. When the treatment gas includes water vapor, the delivery may be achieved using a mass flow meter (MFM), an injection valve, or by commercially available water vapor generators. The treatment gas may be introduced from the first processing region, either through the RPS unit or bypassing the RPS unit, and may further be excited in the first plasma region.

An additional dual channel showerhead, as well as this processing system and chamber, are more fully described in patent application Ser. No. 13/251,714 filed on Oct. 3, 2011, which is hereby incorporated by reference for all purposes to the extent not inconsistent with the claimed features and description herein.

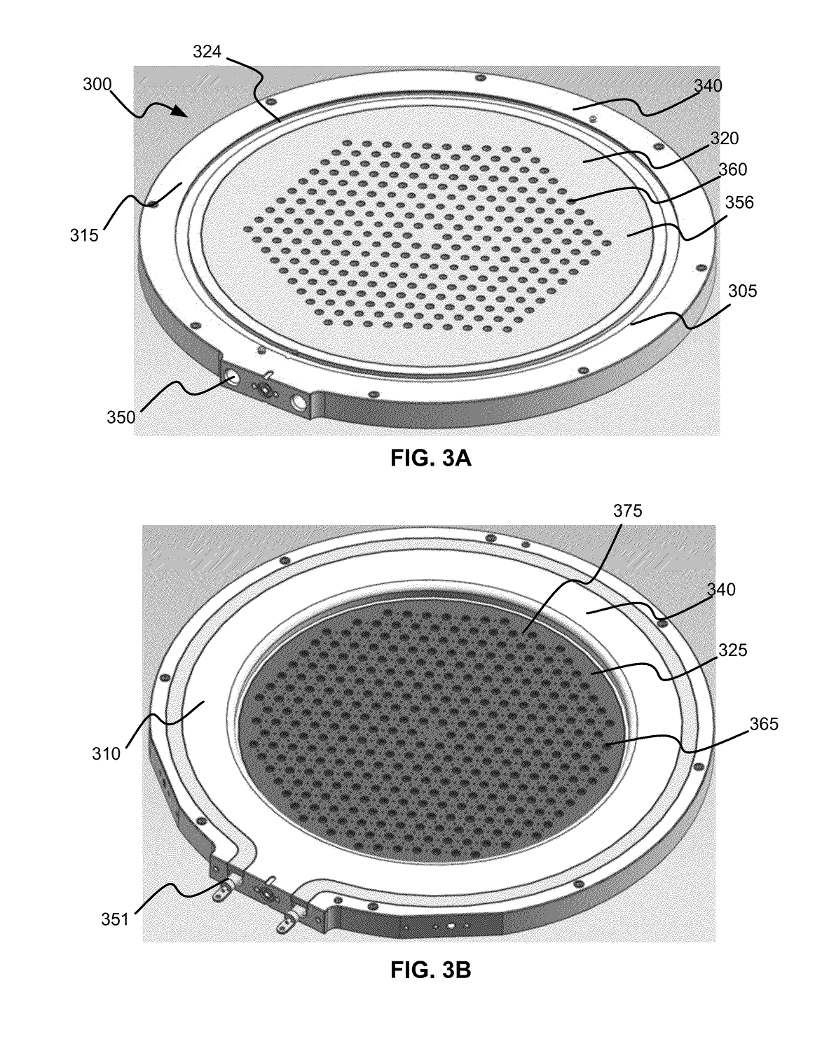

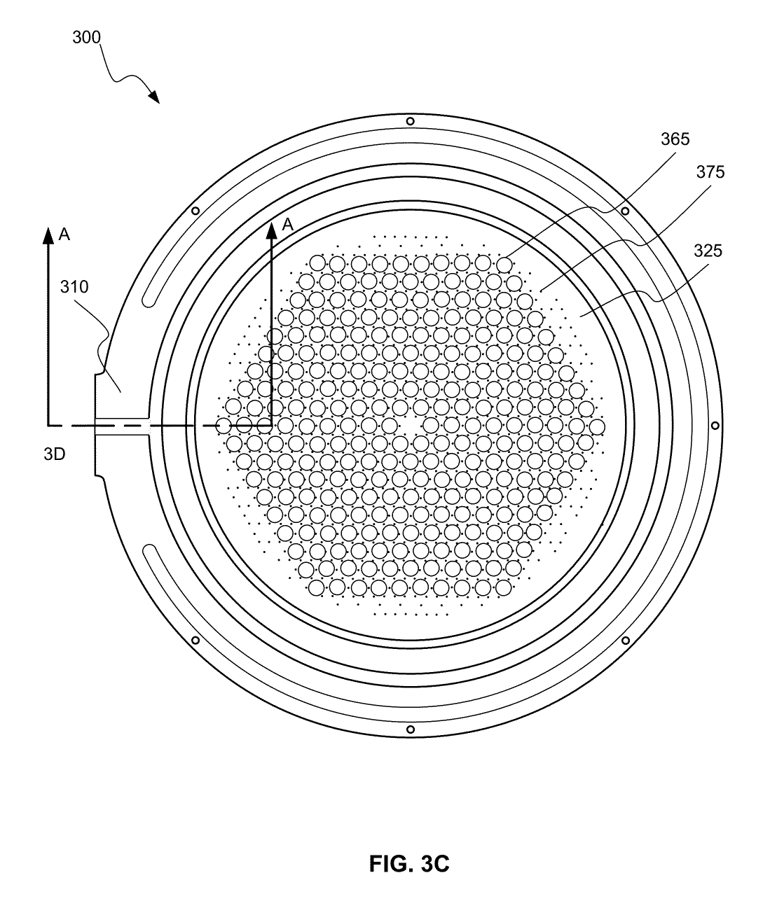

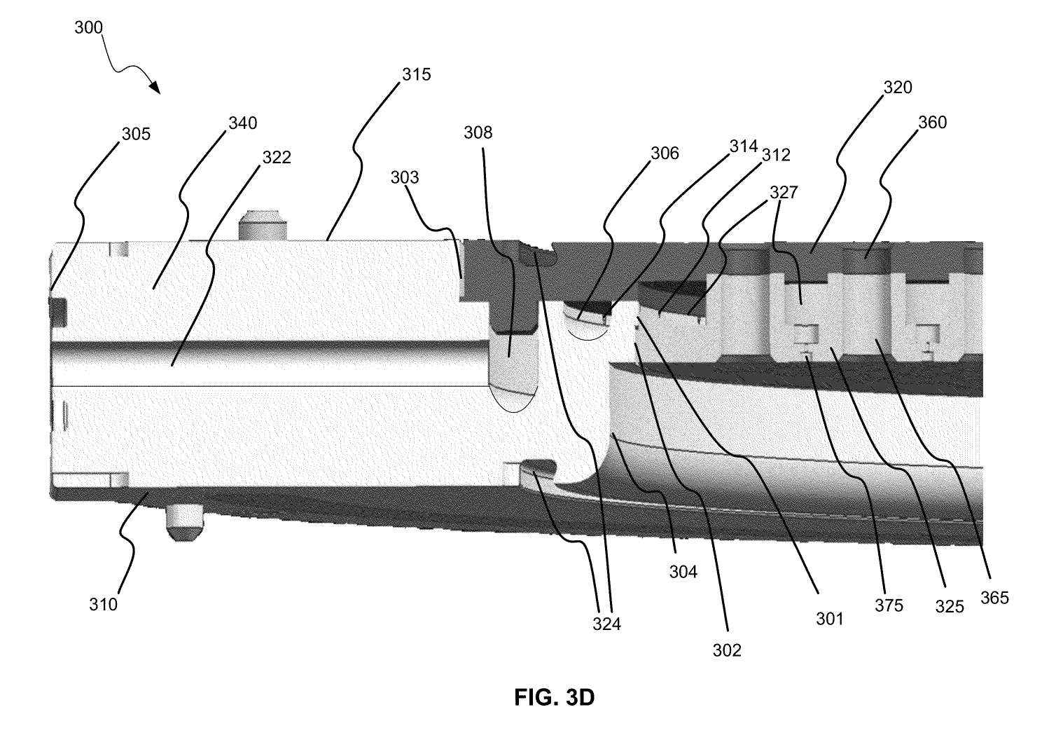

The gas distribution assemblies 225 for use in the processing chamber section 200 are referred to as dual channel showerheads (DCSH) and are detailed in the embodiments described in FIGS. 3A-3D herein. The dual channel showerhead may allow for flowable deposition of a dielectric material, and separation of precursor and processing fluids during operation. The showerhead may alternatively be utilized for etching processes that allow for separation of etchants outside of the reaction zone to provide limited interaction with chamber components and each other prior to being delivered into the processing region.

Referring generally to the showerheads in FIGS. 3A-3D, precursors may be introduced into the processing region by first being introduced into an internal showerhead volume 327 defined in the showerhead 300 by a first manifold 320, or upper plate, and second manifold 325, or lower plate. The manifolds may be perforated plates that define a plurality of apertures. The precursors in the internal showerhead volume 327, typically referred to as the second precursors, may flow into the processing region 233 via apertures 375 formed in the lower plate. This flow path may be isolated from the rest of the process gases in the chamber, and may provide for the precursors to be in an unreacted or substantially unreacted state until entry into the processing region 233 defined between the substrate 255 and a bottom of the lower plate 325. Alternatively, second RPS 202 may be used to excite or produce radical species of the second precursor. These radical species may be maintained separate from the other radical species of the first precursor that may flow through the first apertures 360. Once in the processing region 233, the two precursors may react with each other and the substrate. The second precursor may be introduced into the internal showerhead volume 327 defined in the showerhead 300 through a side channel formed in the showerhead, such as channel 322 as shown in the showerhead embodiments herein. The first precursor gas may be in a plasma state including radicals from the RPS unit or from a plasma generated in the first plasma region. Additionally, a plasma may be generated in the processing region.

FIG. 3A illustrates an upper perspective view of a gas distribution assembly 300. In usage, the gas distribution system 300 may have a substantially horizontal orientation such that an axis of the gas apertures formed therethrough may be perpendicular or substantially perpendicular to the plane of the substrate support (see substrate support 265 in FIG. 2). FIG. 3B illustrates a bottom perspective view of the gas distribution assembly 300. FIG. 3C is a bottom plan view of the gas distribution assembly 300. FIG. 3D is a cross sectional views of an exemplary embodiment of gas distribution assembly 300 taken along line A-A of FIG. 3C.

Referring to FIGS. 3A-3D, the gas distribution assembly 300 generally includes the annular body 340, the upper plate 320, and the lower plate 325. The annular body 340 may be a ring which has an inner annular wall 301 located at an inner diameter, an outer annular wall 305 located at an outer diameter, an upper surface 315, and a lower surface 310. The upper surface 315 and lower surface 310 define the thickness of the annular body 340. A conduit 350 may be formed in the annular body 340 and a cooling fluid may be flowed within the channel that extends around the circumference of the annular body 340. Alternatively, a heating element 351 may be extended through the channel that is used to heat the showerhead assembly.

One or more recesses and/or channels may be formed in or defined by the annular body as shown in disclosed embodiments including that illustrated in FIG. 3D. The annular body may include an upper recess 303 formed in the upper surface, and a first lower recess 302 formed in the lower surface at the inner annular wall 301. The annular body may also include a second lower recess 304 formed in the lower surface 310 below and radially outward from the first lower recess 302. As shown in FIG. 3D, an inner fluid channel 306 may be defined in the upper surface 315, and may be located in the annular body radially inward of the upper recess 303. The inner fluid channel 306 may be annular in shape and be formed the entire distance around the annular body 340. In disclosed embodiments, a bottom portion of the upper recess 303 intersects an outer wall of the inner fluid channel 306 (not shown). The inner fluid channel may also be at least partially radially outward of the second lower recess 304. A plurality of ports 312 may be defined in an inner wall of the inner fluid channel, also the inner annular wall 301 of the annular body 340. The ports 312 may provide access between the inner fluid channel and the internal volume 327 defined between the upper plate 320 and lower plate 325. The ports may be defined around the circumference of the channel at specific intervals, and may facilitate fluid distribution across the entire region of the volume 327 defined between the upper and lower plates. The intervals of spacing between the ports 312 may be constant, or may be varied in different locations to affect the flow of fluid into the volume. The inner and outer walls, radially, of the inner fluid channel 306 may be of similar or dissimilar height. For example, the inner wall may be formed higher than the outer wall to affect the distribution of fluids in the inner fluid channel to avoid or substantially avoid the flow of fluid over the inner wall of the first fluid channel.

Again referring to FIG. 3D, an outer fluid channel 308 may be defined in the upper surface 315 that is located in the annular body radially outward of the inner fluid channel 306. Outer fluid channel 308 may be an annular shape and be located radially outward from and concentric with inner fluid channel 306. The outer fluid channel 308 may also be located radially outward of the first upper recess 303 such that the outer fluid channel 308 is not covered by the upper plate 320, or may be radially inward of the first upper recess 303 as shown, such that upper plate 320 covers the outer fluid channel 308. A second plurality of ports 314 may be defined in the portion of the annular body 340 defining the outer wall of the inner fluid channel 306 and the inner wall of the outer fluid channel 308. The second plurality of ports 314 may be located at intervals of a pre-defined distance around the channel to provide fluid access to the inner fluid channel 306 at several locations about the outer fluid channel 308. In operation, a precursor may be flowed from outside the process chamber to a delivery channel 322 located in the side of the annular body 340. This delivery channel 322 may be in fluid communication with the second RPS 202 through a second access in the processing chamber. The fluid may flow into the outer fluid channel 308, through the second plurality of ports 314 into the inner fluid channel 306, through the first plurality of ports 312 into the internal volume 327 defined between the upper and lower plates, and through the third apertures 375 located in the bottom plate 325. As such, a fluid provided in such a fashion can be isolated or substantially isolated from any fluid delivered into the first plasma region through apertures 360 until the fluids separately exit the lower plate 325.

The upper plate 320 may be a disk-shaped body, and may be coupled with the annular body 340 at the first upper recess 303. The upper plate 320 may thus cover the first fluid channel 306 to prevent or substantially prevent fluid flow from the top of the first fluid channel 306. The upper plate may have a diameter selected to mate with the diameter of the upper recess 303, and the upper plate may comprise a plurality of first apertures 360 formed therethrough. The first apertures 360 may extend beyond a bottom surface of the upper plate 320 thereby forming a number of raised cylindrical bodies (not shown). In between each raised cylindrical body may be a gap. As seen in FIG. 3A, the first apertures 360 may be arranged in a polygonal pattern on the upper plate 320, such that an imaginary line drawn through the centers of the outermost first apertures 360 define or substantially define a polygonal figure, which may be for example, a six-sided polygon.

The lower plate 325 may have a disk-shaped body having a number of second apertures 365 and third apertures 375 formed therethrough, as especially seen in FIG. 3C. The lower plate 325 may have multiple thicknesses, with the thickness of defined portions greater than the central thickness of the upper plate 320, and in disclosed embodiments at least about twice the thickness of the upper plate 320. The lower plate 325 may also have a diameter that mates with the diameter of the inner annular wall 301 of the annular body 340 at the first lower recess 302. The second apertures 365 may be defined by the lower plate 325 as cylindrical bodies extending up to the upper plate 320. In this way, channels may be formed between the first and second apertures that are fluidly isolated from one another, and may be referred to as first fluid channels. Additionally, the volume 327 formed between the upper and lower plates may be fluidly isolated from the channels formed between the first and second apertures. As such, a fluid flowing through the first apertures 360 will flow through the second apertures 365 and a fluid within the internal volume 327 between the plates will flow through the third apertures 375, and the fluids will be fluidly isolated from one another until they exit the lower plate 325 through either the second or third apertures. Third apertures 375 may be referred to as second fluid channels, which extend from the internal volume 327 through the bottom plate 325. This separation may provide numerous benefits including preventing a radical precursor from contacting a second precursor prior to reaching a processing region. By preventing the interaction of the gases, reactions within the chamber may be minimized prior to the processing region in which the reaction is desired.

The second apertures 365 may be arranged in a pattern that aligns with the pattern of the first apertures 360 as described above. In one embodiment, when the upper plate 320 and bottom plate 325 are positioned one on top of the other, the axes of the first apertures 360 and second apertures 365 align. In disclosed embodiments, the upper and lower plates may be coupled with one another or directly bonded together. Under either scenario, the coupling of the plates may occur such that the first and second apertures are aligned to form a channel through the upper and lower plates. The plurality of first apertures 360 and the plurality of second apertures 365 may have their respective axes parallel or substantially parallel to each other, for example, the apertures 360, 365 may be concentric. Alternatively, the plurality of first apertures 360 and the plurality of second apertures 365 may have the respective axis disposed at an angle from about 1° to about 30° from one another. At the center of the bottom plate 325 there may or may not be a second aperture 365.

Referring again to FIG. 3D, a pair of isolation channels, 324 may be formed in the annular body 340. One of the pair of isolation channels 324 may be defined in the upper plate 320, and the other of the pair of isolation channels 324 may be defined in the lower surface 310 of the annular body 340. Alternatively, as shown in FIG. 3A, one of the pair of isolation channels 324 may be defined in the upper surface 315 of the annular body 340. The pair of isolation channels may be vertically aligned with one another, and in disclosed embodiments may be in direct vertical alignment. Alternatively, the pair of isolation channels may be offset from vertical alignment in either direction. The channels may provide locations for isolation barriers such as o-rings in disclosed embodiments.

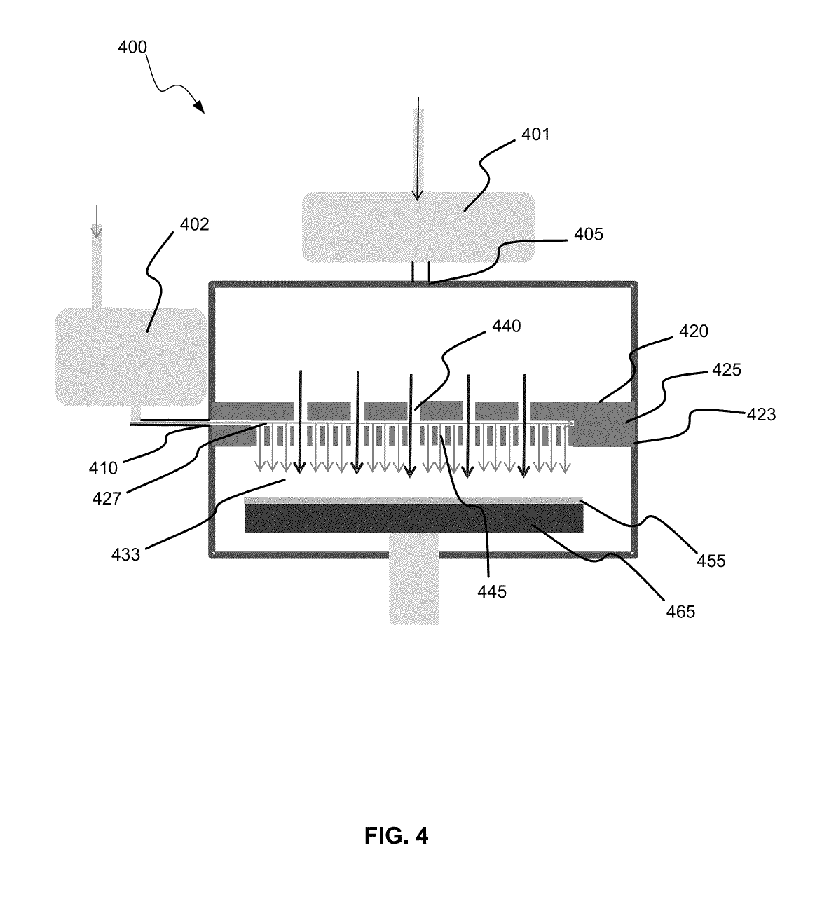

Turning to FIG. 4, a simplified schematic of processing chamber 400 is shown according to the disclosed technology. The chamber 400 may include any of the components as previously discussed, and may be configured to house a semiconductor substrate 455 in a processing region 433 of the chamber. The substrate 455 may be located on a pedestal 465 as shown. Processing chamber 400 may include two remote plasma systems (RPS) 401, 402. A first RPS unit 401 may be fluidly coupled with a first access 405 of the chamber 400, and may be configured to deliver a first precursor into the chamber 400 through the first access 405. A second RPS unit 402 may be fluidly coupled with a second access 410 of the chamber 400, and may be configured to deliver a second precursor into the chamber 400 through the second access 410. First and second plasma units 401, 402 may be the same or different plasma systems. For example, either or both systems may be RF plasma systems, CCP plasma chambers, ICP plasma chambers, magnetically generated plasma systems including toroidal plasma systems, microwave plasma systems, etc., or any other system type capable of forming a plasma or otherwise exciting and/or dissociating molecules therein. The system may be configured to maintain the first and second precursors fluidly isolated from one another until they are delivered to the process region 433 of the chamber 400. First access 405 may be located near to or at the top of the processing chamber 400, and second access 410 may be located near or along one of the side portions of the chamber 400.

Chamber 400 may further include a gas distribution assembly 425 within the chamber. The gas distribution assembly 425, which may be similar in aspects to the dual-channel showerheads as previously described, may be located within the chamber 400 at a top portion of the processing region 433, or above the processing region 433. The gas distribution assembly 425 may be configured to deliver both the first and second precursors into the processing region 433 of the chamber 400. Although the exemplary system of FIG. 4 includes a dual-channel showerhead, it is understood that alternative distribution assemblies may be utilized that maintain first and second precursors fluidly isolated prior to the processing region 433. For example, a perforated plate and tubes underneath the plate may be utilized, although other configurations may operate with reduced efficiency or not provide as uniform processing as the dual-channel showerhead as described.

The gas distribution assembly 425 may comprise an upper plate 420 and a lower plate 423 as previously discussed. The plates may be coupled with one another to define a volume 427 between the plates. The coupling of the plates may be such as to provide first fluid channels 440 through the upper and lower plates, and second fluid channels 445 through the lower plate 423. The formed channels may be configured to provide fluid access from the volume 427 through the lower plate 423, and the first fluid channels 440 may be fluidly isolated from the volume 427 between the plates and the second fluid channels 445. The volume 427 may be fluidly accessible through a side of the gas distribution assembly 425, such as channel 322 as previously discussed. This portion of the gas distribution assembly may be fluidly coupled with the second access 410 in the chamber through which RPS unit 402 may deliver the second precursor.

The chamber may be configured to deliver the first precursor into the processing region 433 of the chamber from the first RPS unit 401, through the first access 405 in the chamber. The first precursor may then be delivered through the first fluid channels 440 in the gas distribution assembly 425. The chamber may additionally be configured to provide the second precursor into the chamber from the second RPS 402 through the second access 410 in the chamber 400. The second precursor may flow through the access 410 and into the gas distribution assembly 425. The second precursor may flow through the gas distribution assembly into the volume 427 defined between the upper and lower plates, and then flow down into the processing region 433 through the second fluid channels 445 in the lower plate 423 of the gas distribution assembly 425. From the coupling and configuration of the upper plate 420 and lower plate 423, the assembly may be configured to prevent the flow of the second precursor through the upper plate 420 of the assembly 425. This may be due to the alignment of apertures in the assembly as discussed previously.

The plasma cavities of the RPS units 401, 402, and any mechanical couplings leading to the chamber accesses 405, 410 may be made of materials based on the first and second precursors selected to be flowed through the RPS units 401, 402. For example, in certain etching operations, a fluorine-containing precursor (e.g., NF₃) may be flowed through either of the first and second RPS units, such as RPS unit 401. When a plasma is formed in the RPS unit 401, the molecules may dissociate into radical ions. If the RPS unit 401 is made of an unaltered aluminum, fluorine radicals may react with the cavity walls forming byproducts such as aluminum fluoride. Accordingly, RPS unit 401 may be formed with a first material that may be for example aluminum oxide, aluminum nitride, or another material with which the first precursor does not interact. The material of the RPS unit 401 may be selected based on the composition of the first precursor, and may be specifically selected such that the precursor does not interact with the chamber components.

Similarly, the second RPS unit 402 may be made of a second material that is selected based on the second precursor. In disclosed embodiments, the first and second material may be different materials. For example, if a hydrogen-containing precursor is flowed through the second RPS 402 and a plasma is formed, dissociated hydrogen radicals may interact with the plasma cavity of the RPS 402. If the chamber is similarly made of aluminum oxide, for example, the hydrogen radicals will interact with the oxide, and may remove the protective coating. Accordingly, RPS unit 402 may be made of a second material different from the first such as aluminum, or another material with which the second precursor does not interact. This may be extended to the gas distribution assembly as well, with the upper surface of the upper plate 420 being made of or coated with the same material used in the first RPS, and the bottom surface of the upper plate 420 and the upper surface of the lower plate 423 being made of or coated with the same material used in the second RPS. Such coatings or materials selections may improve equipment degradation over time. Accordingly, the gas distribution assembly plates may each include multiple plates made of one or more materials.

In operation, one or both of the RPS units 401, 402 may be used to produce a plasma within the unit to at least partially ionize the first and/or second precursor. In one example in which a fluorine-containing precursor and a hydrogen-containing precursor are utilized, the hydrogen-containing precursor may be flowed through the first RPS unit 401 and the fluorine-containing radical may be flowed through the second RPS unit 402. Such a configuration may be based on the travel distances for the radical species. For example, the path to the processing region 433 may be shorter from the first RPS unit 401. Because hydrogen radicals may recombine more quickly than fluorine radicals due to a shorter half-life, the hydrogen-containing radicals may be flowed through the shorter paths. Additionally, a plasma as described earlier may be formed in the region of the chamber 400 above the gas distribution assembly 425 in order to prolong, continue, or enhance the radical species. However, other configurations disclosed may flow the hydrogen-containing precursor through the second RPS unit 402.

The RPS units 401, 402 may be operated at power levels from between below or about 10 W up to above or about 10 or 15 kW in various embodiments. The inventors have advantageously determined that an additional benefit of the disclosed technology is that the power and plasma profile of each RPS unit may be tuned to the particular precursor used. For example, continuing the example with a fluorine-containing precursor and a hydrogen-containing precursor, some conventional systems require that both precursors requiring dissociation be flowed through the same RPS unit. In addition to the potential deterioration of the plasma cavity and RPS unit as discussed above, a plasma profile beneficial to both precursors may not be available. Continuing the example, fluorine-containing precursors including NF₃ may be processed at a relatively low level of power in the RPS unit. By operating the RPS at a power level at or below 100 W, 200 W, 400 W, up to 1000 W or more, the precursor may be dissociated to a lesser degree that does not completely ionize the particles, and includes independent radicals including NF and NF₂ species as well. Additionally, the RPS unit processing the hydrogen-containing precursor may be operated at a much higher power level as complete dissociation may be desired. Accordingly, the RPS unit may be operated between up to or above about 1000 W and up to or above about 10 kW or more. The RF frequency applied in the exemplary processing system may be low RF frequencies less than about 500 kHz, high RF frequencies between about 10 MHz and about 15 MHz or microwave frequencies greater than or about 1 GHz in different embodiments. As such, the first RPS unit 401 may be configured to operate at a first power level that is selected based on the composition of the first precursor, and the second RPS may be configured to operate at a second power level that is selected based on the composition of the second precursor. The two RPS units 401, 402 may be configured to operate at power levels different from one another. Such a configuration may require separate or decoupled power sources, among other changes.

Additional flexibility may be provided by operating one of the RPS units but not the other. For example, a fluorine-containing precursor may be flowed through the first RPS unit 401 that is configured to operate at a power level that may be lower based on the precursor. A hydrogen-containing precursor may be flowed through the second RPS unit 402 in which a plasma is not formed such that the molecular precursor flows to the processing region 433. When the first and second precursors separately exit the gas distribution assembly 425 they may interact, and the first precursor that has been at least partially radicalized in RPS unit 401 may ionize a portion of the second precursor, in which case power efficiency of the system may be improved. Based on these examples, it is understood that many aspects may be reversed or changed in disclosed embodiments of the technology based on various operational characteristics.

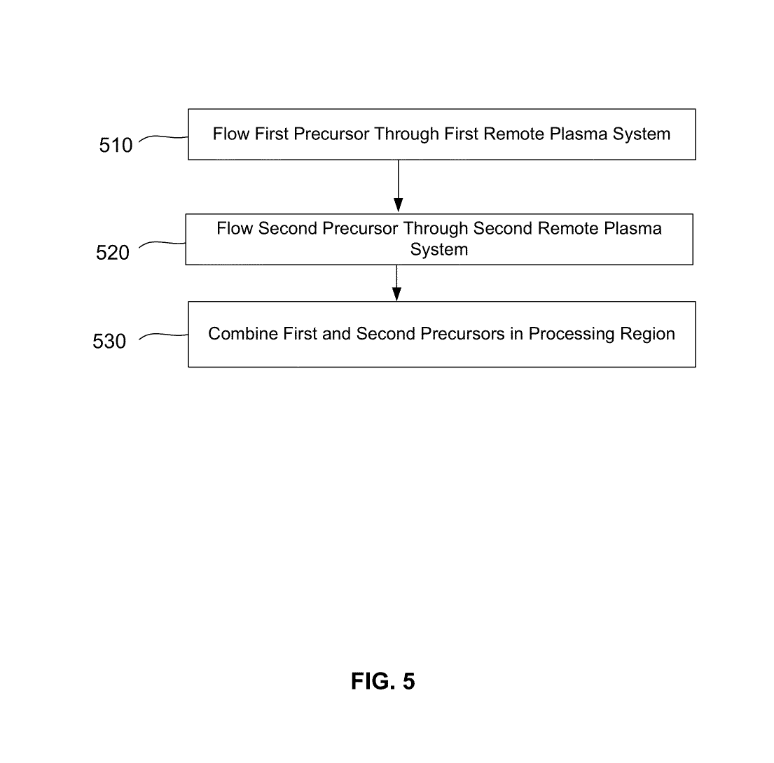

In order to better understand and appreciate the invention, reference is now made to FIG. 5 which is a flow chart of an etch process, specifically a silicon-selective etch, according to disclosed embodiments. It is understood that the technology can similarly be utilized for deposition processes. Silicon may be amorphous, crystalline, or polycrystalline (in which case it is usually referred to as polysilicon). Prior to the first operation, a structure may be formed in a patterned substrate. The structure may possess separate exposed regions of silicon and silicon oxide. Previous deposition and formation processes may or may not have been performed in the same chamber. If performed in a different chamber, the substrate may be transferred to a system such as that described above.

A first precursor such as a hydrogen-containing precursor, may be flowed into a first plasma region separate from the substrate processing region at operation 510. The separate plasma region may be referred to as a remote plasma region herein and may be within a distinct module from the processing chamber or a compartment within the processing chamber. Generally speaking, a hydrogen-containing precursor may be flowed into the first plasma region in which it is excited in a plasma, and the hydrogen-containing precursor may comprise at least one precursor selected from H₂, NH₃, hydrocarbons, or the like. A flow of a second precursor such as nitrogen trifluoride, or a different fluorine-containing precursor, may be introduced into a second remote plasma system at operation 520 where it is excited in a plasma. The first and second plasma systems may be operated in any fashion as previously discussed, and in disclosed embodiments the hydrogen-containing precursor and the fluorine-containing precursor may be flowed through the alternative RPS unit. Additionally, only one of the remote plasma systems may be operated in disclosed embodiments. The flow rate of the nitrogen trifluoride may be low relative to the flow rate of the hydrogen to effect a high atomic flow ratio H:F as will be quantified shortly. Other sources of fluorine may be used to augment or replace the nitrogen trifluoride. In general, a fluorine-containing precursor may be flowed into the second remote plasma region and the fluorine-containing precursor comprises at least one precursor selected from the group consisting of atomic fluorine, diatomic fluorine, bromine trifluoride, chlorine trifluoride, nitrogen trifluoride, hydrogen fluoride, fluorinated hydrocarbons, sulfur hexafluoride, and xenon difluoride.

The plasma effluents formed in the remote plasma regions of the first and second precursors may then be separately flowed into and then combined in the substrate processing region at operation 530. The patterned substrate may be selectively etched such that the exposed silicon is removed at a rate at least or about seventy times greater than the exposed silicon oxide. The technology may involve maintenance of a high atomic flow ratio of hydrogen (H) to fluorine (F) in order achieve high etch selectivity of silicon. Some precursors may contain both fluorine and hydrogen, in which case the atomic flow rate of all contributions are included when calculating the atomic flow ratio described herein. The preponderance of hydrogen may help to hydrogen terminate exposed surfaces on the patterned substrate. Under the conditions described herein, hydrogen termination may be metastable on only the silicon surfaces. Fluorine from the nitrogen trifluoride or other fluorine-containing precursor displaces the hydrogen on the silicon surface and creates volatile residue which leaves the surface and carries silicon away. Due to the strong bond energies present in the other exposed materials, the fluorine may be unable to displace the hydrogen of the other hydrogen terminated surfaces (and/or is unable to create volatile residue to remove the other exposed material).

In one example, a gas flow ratio (H₂:NF₃) greater than or about 15:1, or in general terms, greater than or about an atomic flow ratio of between 10:1, was found to achieve etch selectivity (silicon:silicon oxide or silicon:silicon nitride) of greater than or about 70:1. The etch selectivity (silicon:silicon oxide or silicon:silicon nitride) may also be greater than or about 100:1, greater than or about 150:1, greater than or about 200:1, greater than or about 250:1 or greater than or about 300:1 in disclosed embodiments, or between or among any of these ranges. Regions of exposed tungsten, titanium nitride, or other metals may also be present on the patterned substrate and may be referred to as exposed metallic regions. The etch selectivity (silicon:exposed metallic region) may be greater than or about 100:1, greater than or about 150:1, greater than or about 200:1, greater than or about 250:1, greater than or about 500:1, greater than or about 1000:1, greater than or about 2000:1 or greater than or about 3000:1 in disclosed embodiments. The reactive chemical species are removed from the substrate processing region and then the substrate is removed from the processing region.

The presence of the high flow of hydrogen-containing precursor, as described herein, ensures that silicon, silicon oxide and silicon nitride maintain a hydrogen-terminated surface during much of the processing. The fluorine-containing precursor and/or the hydrogen-containing precursor may further include one or more relatively inert gases such as He, N₂, Ar, or the like. The inert gas can be used to improve plasma stability and/or to carry liquid precursors to the remote plasma region. Flow rates and ratios of the different gases may be used to control etch rates and etch selectivity. In an embodiment, the fluorine-containing gas includes NF₃ at a flow rate of between about 1 sccm (standard cubic centimeters per minute) and 30 sccm, and H₂ at a flow rate of between about 500 sccm and 5,000 sccm, He at a flow rate of between about 0 sccm and 3000 sccm, and Ar at a flow rate of between about 0 sccm and 3000 sccm. The atomic flow ratio H:F may be kept high in disclosed embodiments to reduce or eliminate solid residue formation on silicon oxide. The formation of solid residue consumes some silicon oxide which may reduce the silicon selectivity of the etch process. The atomic flow ratio H:F may be greater than or about twenty five (i.e. 25:1), greater than or about 30:1 or greater than or about 40:1 in embodiments of the technology.

By maintaining the precursors fluidly separate, corrosion and other interaction with the RPS systems may be reduced or eliminated. As described above, the RPS units and distribution components including the gas distribution assembly may be made of materials selected based on the precursors being delivered, and thus selected to prevent reaction between the ionized precursors and the equipment.

An ion suppressor may be used to filter ions from the plasma effluents during transit from the remote plasma region to the substrate processing region in embodiments of the invention. The ion suppressor functions to reduce or eliminate ionically charged species traveling from the plasma generation region to the substrate. Uncharged neutral and radical species may pass through the openings in the ion suppressor to react at the substrate. It should be noted that complete elimination of ionically charged species in the reaction region surrounding the substrate is not always the desired goal. In many instances, ionic species are required to reach the substrate in order to perform the etch and/or deposition process. In these instances, the ion suppressor helps control the concentration of ionic species in the reaction region at a level that assists the process. In disclosed embodiments the upper plate of the gas distribution assembly may include an ion suppressor.

The temperature of the substrate may be greater than 0° C. during the etch process. The substrate temperature may alternatively be greater than or about 20° C. and less than or about 300° C. At the high end of this substrate temperature range, the silicon etch rate may drop. At the lower end of this substrate temperature range, silicon oxide and silicon nitride may begin to etch and thus the selectivity may drop. In disclosed embodiments, the temperature of the substrate during the etches described herein may be greater than or about 30° C. while less than or about 200° C. or greater than or about 40° C. while less than or about 150° C. The substrate temperature may be below 100° C., below or about 80° C., below or about 65° C. or below or about 50° C. in disclosed embodiments.

The data further show an increase in silicon etch rate as a function of process pressure (for a given hydrogen:fluorine atomic ratio). However, for an atomic flow rate ratio of about 50:1 H:F, increasing the pressure above 1 Torr may begin to reduce the selectivity. This is suspected to result from a higher probability of combining two or more fluorine-containing effluents. The etch process may then begin to remove silicon oxide, silicon nitride, and other materials. The pressure within the substrate processing region may be below or about 10 Torr, below or about 5 Torr, below or about 3 Torr, below or about 2 Torr, below or about 1 Torr or below or about 750 mTorr in disclosed embodiments. In order to ensure adequate etch rate, the pressure may be above or about 0.05 Torr, above or about 0.1 Torr, above or about 0.2 Torr or above or about 0.4 Torr in embodiments of the invention. Additional examples, process parameters, and operational steps are included in previously incorporated application Ser. No. 13/439,079 to the extent not inconsistent with the delivery mechanisms described herein.

In the preceding description, for the purposes of explanation, numerous details have been set forth in order to provide an understanding of various embodiments of the present invention. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the disclosed embodiments. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “an aperture” includes a plurality of such apertures, and reference to “the plate” includes reference to one or more plates and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or steps, but they do not preclude the presence or addition of one or more other features, integers, components, steps, acts, or groups.

What is claimed is:

1. A system for semiconductor processing, the system comprising:
a chamber configured to house a semiconductor substrate in a processing region of the chamber;
a first remote plasma system fluidly coupled with a first access of the chamber and configured to deliver a first precursor into the chamber through the first access;
a second remote plasma system fluidly coupled with a second access of the chamber and configured to deliver a second precursor into the chamber through the second access.

2. The system of claim 1, wherein the system is configured to maintain the first and second precursors fluidly isolated from one another until they are delivered to the processing region of the chamber.

3. The system of claim 1, wherein the first access is located near or at a top portion of the chamber and the second access is located near or at a side portion of the chamber.

4. The system of claim 1, further comprising a gas distribution assembly located within the chamber at a top portion of or above the processing region of the chamber and configured to deliver both the first and second precursors into the processing region of the chamber.

5. The system of claim 4, wherein the gas distribution assembly comprises an upper plate and a lower plate, wherein the upper and lower plates are coupled with one another to define a volume between the plates, wherein the coupling of the plates provides first fluid channels through the upper and lower plates and second fluid channels through the lower plate and configured to provide fluid access from the volume through the lower plate, and wherein the first fluid channels are fluidly isolated from the volume between the plates and the second fluid channels.

6. The system of claim 5, wherein the volume is fluidly accessible through a side of the gas distribution assembly fluidly coupled with the second access in the chamber.

7. The system of claim 6, wherein the chamber is configured to provide the first precursor into the processing region of the chamber from the first remote plasma system through the first access in the chamber and through the first fluid channels in the gas distribution assembly.

8. The system of claim 6, wherein the chamber is configured to provide the second precursor into the chamber from the second remote plasma system through the second access in the chamber into the volume defined between the upper and lower plates and into the processing region of the chamber through the second fluid channels in the gas distribution assembly.

9. The system of claim 7, wherein the gas distribution assembly is configured to prevent the flow of the second precursor through the upper plate of the gas distribution assembly.

10. The system of claim 1, wherein the first remote plasma system comprises a first material and the second remote plasma system comprises a second material.

11. The system of claim 10, wherein the first material is selected based on the composition of the first precursor.

12. The system of claim 11, wherein the second material is selected based on the composition of the second precursor.

13. The system of claim 12, wherein the first material and second material are different materials.

14. The system of claim 1, wherein the first and second remote plasma systems are selected from the group consisting of radio frequency plasma units, capacitively coupled plasma units, inductively coupled plasma units, microwave plasma units, and toroidal plasma units.

15. The system of claim 1, wherein the first and second remote plasma systems are configured to operate at power levels between about 10 W to above or about 10 kW.

16. The system of claim 15, wherein the first remote plasma system is configured to operate at a first power level that is selected based on the composition of the first precursor.

17. The system of claim 16, wherein the second remote plasma system is configured to operate at a second power level that is selected based on the composition of the second precursor.

18. The system of claim 17, wherein the system is configured to operate the first and second remote plasma units at power levels different from one another.

19. A method of operation for a semiconductor processing chamber, the method comprising:
flowing a first precursor through a first remote plasma system into a semiconductor processing chamber; and
flowing a second precursor through a second remote plasma system into the semiconductor processing chamber, wherein the first and second precursors are combined in a processing region of the processing chamber.

20. The method of claim 19, wherein the first precursor comprises a fluorine-containing precursor, and the second precursor comprises a hydrogen-containing precursor.
